(19) United States
(12) Patent Application Publication
(10) Pub. No.: US 2026/0247838 A1
(43) Pub. Date: Aug. 20, 2026

(54) FOLDING DISPLAY DEVICE HAVING SUPPORT STRUCTURE AND ELECTRONIC DEVICE INCLUDING THE SAME

(71) Applicant: SAMSUNG DISPLAY CO., LTD., YONGIN-SI (KR)

(72) Inventors: DASOM GU, Yongin-si (KR); KYUNGMIN CHOI, Yongin-si (KR); DOHOON KIM, Yongin-si (KR); JI-HOON KIM, Yongin-si (KR); SUNJE PARK, Yongin-si (KR); SUNGGUK AN, Yongin-si (KR)

(21) Appl. No.: 19/462,299

(22) Filed: Jan. 28, 2026

(30) Foreign Application Priority Data
Feb. 4, 2025 (KR) 10-2025-0013853

(51) Int. Cl. H10K 59/80; H10K 102/00

(52) U.S. Cl. CPC H10K 59/873; H10K 2102/311

(57) ABSTRACT

A display device includes a display module including a first non-folding area, a second non-folding area, and a folding area disposed between the first non-folding and second non-folding areas. The first non-folding area, the second non-folding area, and the folding area are disposed in a first direction. A panel support is disposed under the display module. A plate is disposed under the panel support. A first auxetic structure having a negative Poisson’s ratio is disposed between the panel support and the plate in the folding area. The first auxetic structure includes auxetic foam.

### CROSS-REFERENCE TO RELATED APPLICATION

This application claims priority under 35 U.S.C. §119 to Korean Patent Application No. 10-2025-0013853, filed with the Korean Intellectual Property Office on Feb. 4, 2025, the disclosure of which is fully incorporated by reference herein.

### TECHNICAL FIELD

The present disclosure relates to a display device and, more specifically, to a folding display device having a support structure and an electronic device including the same.

### DISCUSSION OF THE RELATED ART

Electronic devices such as smartphones, tablets, laptop/notebook computers, car navigation systems, and smart televisions are being developed. These electronic devices are equipped with display devices which operate to provide visual information to a user.

Various types of display devices are being developed to improve UX/UI for better user satisfaction. For example, flexible display devices are being developed. In particular, development is underway to improve impact absorption, strength, tensile strength and resilience in the folding area of the flexible display device.

### SUMMARY

A display device includes a display module that includes a first non-folding area, a second non-folding area, and a folding area disposed between the first non-folding area and the second non-folding area, the first non-folding area, the second non-folding area, and the folding area disposed in a first direction. A panel support is disposed under the display module. A plate is disposed under the panel support. In the folding area, a first auxetic structure with a negative Poisson's ratio is disposed between the panel support and the plate, and the first auxetic structure includes an auxetic foam.

The first auxetic structure may include a first stretchable pattern.

An aperture ratio of the first auxetic structure, when in a non-folded state, may be 10% or less.

A second auxetic structure may be disposed between the panel support and the display module in the folding area.

The second auxetic structure may include the auxetic foam.

The second auxetic structure may include a second stretchable pattern.

A cushion with a positive Poisson's ratio may be further included at an edge of the second auxetic structure in the first direction.

The plate may include a first plate and a second plate disposed in the first direction, and the display device may further include a third auxetic structure disposed between the first plate and the second plate, and the third auxetic structure may include the auxetic foam.

The third auxetic structure may be attached to either the first plate or the second plate.

The auxetic foam may include at least one of urethane, expanded polytetrafluoroethylene (ePTFE) such as GORE-TEX, polyvinyl chloride (PVC), polymethacrylimide (PMI), or low-density polyethylene (LDPE).

A display device includes a display module including a first non-folding area, a second non-folding area, and a folding area disposed between the first non-folding area and the second non-folding area, the first non-folding area, the second non-folding area, and the folding area disposed in a first direction. A panel support is disposed under the display module. A plate is disposed under the panel support, including a first plate overlapping the first non-folding area and a second plate overlapping the second non-folding area. A first auxetic structure having a negative Poisson’s ratio is disposed between the panel support and the plate in the folding area, and the first auxetic structure includes a first stretchable pattern.

The aperture ratio of the first auxetic structure, when in a non-folded state, may be 10% or less.

A second auxetic structure may be disposed between the panel support and the display module in the folding area.

The second auxetic structure and the first auxetic structure may include an auxetic foam.

The second auxetic structure may include a second stretchable pattern.

A cushion having a positive Poisson's ratio may be further included at the edge of the second auxetic structure in the first direction.

A third auxetic structure may further be disposed between the first plate and the second plate, and the third auxetic structure may include an auxetic foam.

The third auxetic structure can be attached to either the first plate or the second plate.

The auxetic foam may include at least one of urethane, expanded polytetrafluoroethylene (ePTFE), for example, GORE-TEX, polyvinyl chloride (PVC), polymethacrylimide (PMI), or low-density polyethylene (LDPE).

An electronic device includes a display device, a processor, a memory and a power module. The display device includes a display module including a first non-folding area, a second non-folding area, and a folding area disposed between the first non-folding area and the second non-folding area. The first non-folding area, the second non-folding area, and the folding area are disposed in a first direction. A panel support is disposed under the display module. A plate is disposed under the panel support. A first auxetic structure having a negative Poisson’s ratio is disposed between the panel support and the plate in the folding area, and the first auxetic structure includes an auxetic foam.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIGS. 1A, 1B, and 1C, are perspective views of an electronic device according to an embodiment of the disclosure.

FIG. 2A is an exploded perspective view of an electronic device according to an embodiment of the disclosure.

FIG. 2B is a block diagram of an electronic device according to an embodiment of the disclosure.

FIG. 3A is a plan view of a display panel according to an embodiment of the disclosure.

FIG. 3B is a plan view of a portion of a display panel according to an embodiment of the disclosure.

FIG. 4 is a cross-sectional view of an example display module taken along line I-I’ of FIG. 2A.

FIG. 5 is a cross-sectional view of a portion of a display module according to an embodiment of the disclosure.

FIG. 6 is a cross-sectional view of an example of a display device cut along line II-II’ of FIG. 3A.

FIG. 7 is a cross-sectional view of an example display device cut along line II-II’ of FIG. 3A.

FIG. 8 is a block diagram of an electronic device according to an embodiment of the disclosure.

FIG. 9 is a schematic diagram of an electronic device according to various embodiments.

### DETAILED DESCRIPTION

The disclosure may undergo various modifications and have various embodiments; therefore, specific embodiments are illustrated in the drawings and described in detail in the detailed description. The effects and features of the disclosure and the methods for achieving them will become clear with reference to the embodiments described in detail under together with the drawings. However, the disclosure is not necessarily limited to the embodiments disclosed under and may be implemented in various forms.

In the embodiments below, the terms such as first, second, etc. are not necessarily used in a limiting sense but are used for the purpose of distinguishing one component from another.

In the embodiments below, singular expressions include plural meanings unless the context clearly indicates otherwise.

In the embodiments below, terms such as “include” or “have” indicate the presence of a feature or component described in the specification, and do not necessarily exclude in advance the possibility that one or more other features or components may be added.

In the embodiments below, when a unit, region, or component is described as being "on" or "above" another unit, region, or component, it includes not only the case where it is directly above the other part, but also the case where another unit, region, component, etc. is interposed in between.

In the embodiments below, terms such as connect or combine do not necessarily mean a direct and/or fixed connection or combination of two members, unless the context clearly indicates otherwise, and do not exclude the presence of other members between the two members.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Hereinafter, embodiments of the disclosure will be described in detail with reference to the attached drawings. To the extent that an element is not described in detail with respect to this figure, it may be understood that the element is at least similar to a corresponding element that has been described elsewhere within the present disclosure.

Embodiments of the present disclosure relate to a flexible display device designed to enhance durability and user experience in electronic products such as smartphones, tablets, and foldable screen devices. The display device may include a display module divided into two non-folding areas and a folding area disposed between them, all disposed along a single axis. Beneath this display module lies a panel support and, further below, a plate structure that together provide mechanical stability. To address the challenges inherent in foldable displays, particularly impact resistance, creasing, and mechanical fatigue in the folding region, embodiments of the present disclosure introduce auxetic structures, which are materials exhibiting a negative Poisson’s ratio, meaning they expand laterally when stretched rather than contracting like conventional materials.

Within the folding area, the device incorporates a first auxetic structure made from auxetic foam, which may include materials such as urethane, expanded polytetrafluoroethylene (ePTFE), for example, GORE-TEX, PVC, PMI, or LDPE. This auxetic foam is engineered with a stretchable pattern that allows it to elongate and recover its shape effectively during folding and unfolding motions. By utilizing this unique material, embodiments of the present disclosure may improve the folding area’s capacity to absorb shocks, resist permanent deformation, and maintain high tensile strength and resilience, thereby mitigating the creasing phenomenon often observed in foldable screens. Additionally, the auxetic structure’s design enables it to restrict the penetration of foreign substances and moisture, safeguarding the delicate internal components of the display.

Beyond the first auxetic layer, embodiments of the present disclosure may include additional auxetic structures strategically placed between the panel support and the display module, as well as between adjacent plates under the panel support. These supplementary auxetic layers further distribute mechanical stress during folding and enhance the overall robustness of the device. Altogether, the combination of innovative auxetic materials and thoughtfully layered architecture offers a significant advancement in flexible display technology, promising more reliable and longer-lasting foldable electronic devices.

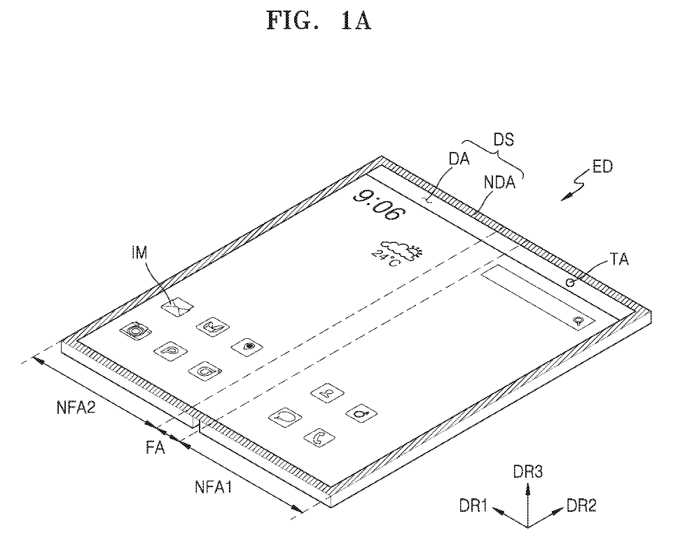

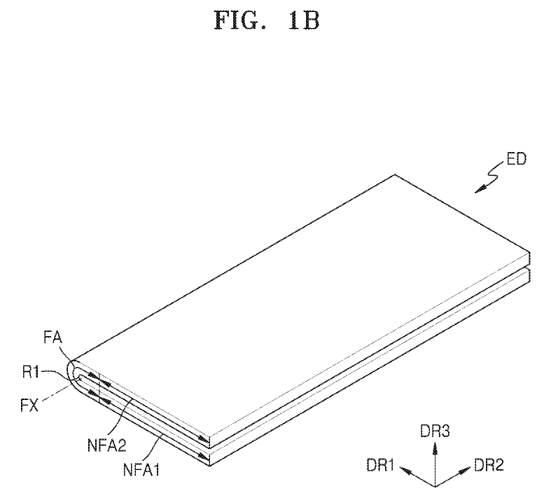

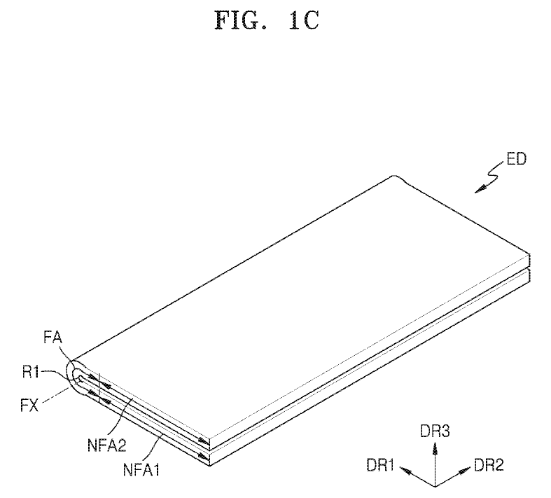

FIGS. 1A to 1C are perspective views of an electronic device according to an embodiment of the disclosure. FIG. 1A shows an unfolded state, and FIGS. 1B and 1C show a folded state.

Referring to FIGS. 1A to 1C, an electronic device ED, according to an embodiment of the disclosure, may include a display surface DS defined by a first direction DR1 and a second direction DR2 intersecting the first direction DR1. The electronic device ED may provide an image IM to a user through the display surface DS.

The display surface DS may include a display area DA and a non-display area NDA surrounding the display area DA. The display area DA may display an image IM, and the non-display area NDA might not display the image IM. The non-display area NDA may surround the display area DA. However, not necessarily limited to the present embodiment, the shape of the display area DA and the shape of the non-display area NDA may be modified.

The display surface DS may include a sensing area TA. The sensing area TA may be a portion of the display area DA. The sensing area TA may have higher light transmittance than other areas of the display area DA. Hereinafter, other areas of the display area DA excluding the sensing area TA may be defined as general display areas.

Optical signals, such as visible light or infrared light, may be transferred to the sensing area TA. The electronic device ED may capture external images via visible light passing through the sensing area TA, or determine the accessibility of external objects via infrared light. FIG. 1A illustrates one sensing area TA, but the number of the sensing area of the disclosure is not necessarily limited thereto, and there may be a plurality of sensing areas.

Hereinafter, the direction substantially perpendicular to the plane defined by the first direction DR1 and the second direction DR2 is defined as a third direction DR3. The third direction DR3 is the standard for distinguishing the front and back of each member. In this specification, “on the plane” may be defined as a state viewed from the third direction DR3. Hereinafter, the first to third directions DR1, DR2, and DR3 are directions indicated by the first to third direction axes, respectively, and refer to the same drawing symbols.

The electronic device ED may include a folding area FA and a plurality of non-folding areas NFA1 and NFA2. The non-folding areas NFA1 and NFA2 may include a first non-folding area NFA1 and a second non-folding area NFA2 In the first direction DR1, the folding area FA may be disposed between the first non-folding area NFA1 and the second non-folding area NFA2.

As illustrated in FIG. 1B, the folding area FA may be folded based on a folding axis FX parallel to the second direction DR2. The folding area FA may have a preset curvature and radius of curvature R1. The first non-folding area NFA1 and the second non-folding area NFA2 may face each other, and the electronic device ED may be inner-folded so that the display surface DS is not exposed to the outside. Thus, in the inner-folded state, the display is protected from impact.

In an embodiment of the present disclosure, the electronic device ED may be outer-folded so that the display surface DS is exposed to the outside. Thus, in the outer-folded state, the display remains viewable.

In an embodiment of the present disclosure, the electronic device ED may be configured such that an in-folding or out-folding operation is alternately repeated from an unfolding operation, but is not necessarily limited thereto. In an embodiment of the present disclosure, the electronic device ED may be configured to select any one of an unfolding operation, an in-folding operation, and an out-folding operation.

Thus, a given electronic device ED may be capable of either in-folding or out-folding or the electronic device ED may be capable of both in-folding and out-folding.

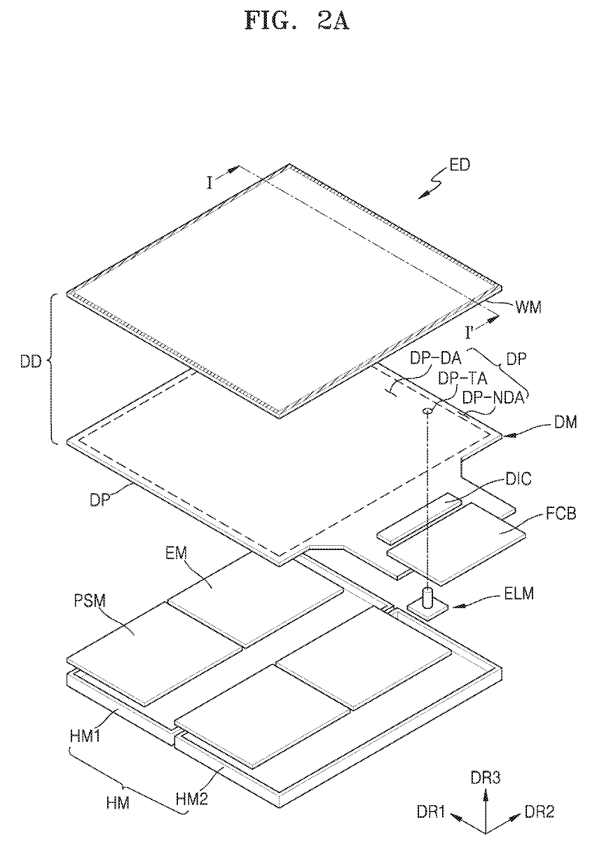

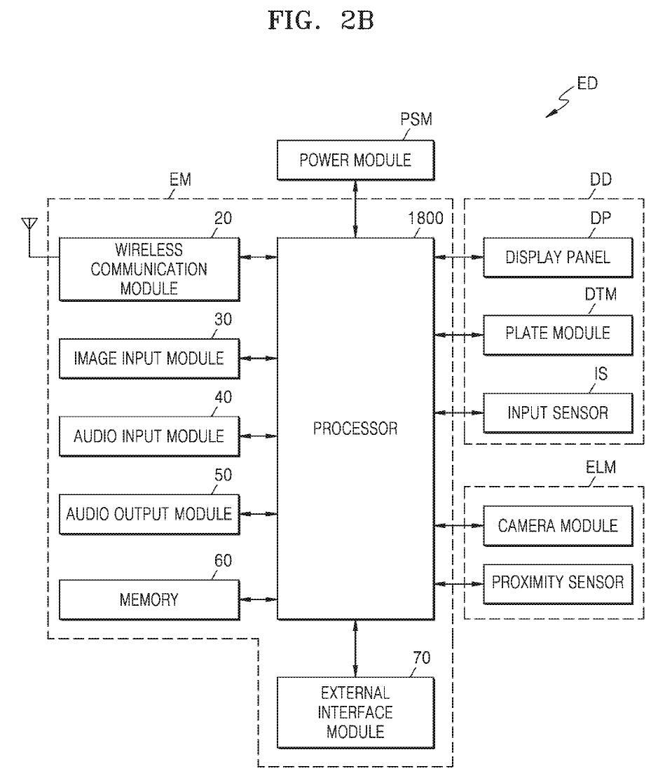

As illustrated in FIG. 1B, the distance between the first non-folding area NFA1 and the second non-folding area NFA2 may be substantially equal to a radius of curvature R1, but as illustrated in FIG. 1C, the distance between the first non-folding area NFA1 and the second non-folding area NFA2 may be smaller than the radius of curvature R1. FIGS. 1B and 1C are diagrams based on the display surface DS, and a housing (see HM of FIG. 2A) forming the exterior of the electronic device ED may be in contact at end areas of the first non-folding area NFA and the second non-folding area NFA2.

FIG. 2A is an exploded perspective view of an electronic device according to an embodiment of the present disclosure, and FIG. 2B is a block diagram of an electronic device according to an embodiment of the disclosure.

As illustrated in FIGS. 2A and 2B, the electronic device ED may include a display device DD, an electronic module EM, an electro-optical module ELM, a power module PSM, and a housing HM. The electronic device ED may further include a mechanical structure for controlling the folding operation of the display device DD.

The display device DD generates images and detects external input. The display device DD includes a window WM and a display module DM. The window WM provides the front of the electronic device ED. A detailed description of the window WM will be provided later.

A display module DM may include at least a display panel DP. In FIG. 2A, only the display panel DP among the laminated structures of the display module DM is illustrated, but in reality, the display module DM may further include a plurality of configurations disposed on the upper side of the display panel DP. A detailed description of the laminated structure of the display module DM will be provided later.

The display panel DP is not particularly limited and may be an emissive display panel such as an organic light-emitting display panel or a quantum dot light-emitting display panel, for example. The display panel DP may be a display panel including ultra-small light-emitting elements such as micro LEDs or nano LEDs.

The display panel DP includes a display area DP-DA and a non-display area DP-NDA corresponding to the display area DA, see FIG. 1A and the non-display area NDA, see FIG. 1A of the electronic device ED. In this specification, "a region/portion corresponds to another region/portion" means overlapping and is not necessarily limited to being the same in area.

The display panel DP may include a sensing area DP-TA corresponding to the sensing area TA of FIG. 1A. The sensing area TA may be an area with lower resolution than the display area DP-DA. A detailed description of the sensing area DP-TA will be given later.

As illustrated in FIG. 2A, a driver chip DIC may be disposed on a non-display area DP-NDA of a display panel DP. A flexible circuit board FCB may be bonded to the non-display area DP-NDA of the display panel DP. A flexible circuit board FCB may be connected to the main circuit board. The main circuit board may be a single electronic component that constitutes an electronic module EM.

A driver chip DIC may include driving elements for driving pixels of a display panel DP, such as a data driving circuit. In FIG. 2A, a structure in which a driver chip DIC is mounted on a display panel DP is illustrated, but the present disclosure is not necessarily limited thereto. For example, the driver chip DIC may be mounted on a flexible circuit board FCB.

As illustrated in FIG. 2B, the display device DD may further include an input sensor IS and a plate module DTM as an optional embodiment. The input sensor IS may detect user input. The capacitive input sensor IS may be disposed on the upper side of the display panel DP. The plate module DTM may include a digitizer, which detects input from a stylus/pen. A plate module DTM including an electromagnetic induction-type digitizer may be disposed under the display panel DP.

The electronic module EM may include a processor 1800, a wireless communication module 20 (such as a radio transceiver), an image input module 30 (such as a camera), an audio input module 40 (such as a microphone), an audio output module 50 (such as a speaker), a memory 60, and an external interface module 70. An electronic module EM may include a main circuit board, and the modules may be mounted on the main circuit board or electrically connected to the main circuit board via a flexible circuit board. The electronic module EM is electrically connected to the power module PSM.

Referring to FIG. 2B, an electronic module EM may be disposed in each of the first housing HM1 and the second housing HM2, and a power module PSM may be disposed in each of the first housing HM1 and the second housing HM2. The electronic module EM disposed in the first housing HM1 and the electronic module EM disposed in the second housing HM2 may be electrically connected via a flexible circuit board.

The processor 1800 controls the overall operation of the electronic device ED. For example, the processor 1800 activates or deactivates a display device DD in response to user input. The processor 1800 may control the image input module 30, the audio input module 40, the audio output module 50, etc. in accordance with user input. The processor 1800 may include at least one microprocessor.

The wireless communication module 20 may transmit/receive wireless signals with other terminals using a Bluetooth or Wi-Fi line. The wireless communication module 20 may transmit/receive voice signals using general communication lines. The wireless communication module 20 may include a plurality of antenna modules.

The image input module 30 processes the image signal and converts it into image data that may be displayed on the display device DD. The audio input module 40 receives an external audio signal through a microphone in recording mode, voice recognition mode, etc., and converts it into electrical voice data. The audio output module 50 converts audio data received from the wireless communication module 20 or audio data stored in the memory 60 and outputs it to the outside.

The external interface module 70 serves as an interface that connects to an external charger, wired/wireless data port, card socket (e.g., memory card, SIM/UIM card), etc.

The power module PSM supplies the power required for the overall operation of the electronic device ED. The power module PSM may include a conventional battery device.

An electro-optical module ELM may be an electronic component that outputs or receives an optical signal. An electro-optical module ELM may include a camera module and/or a proximity sensor. The camera module captures images of the outside through the sensing area DP-TA.

The housing HM illustrated in FIG. 2A is coupled with a display device DD, in particular a window WM, to accommodate the other modules. The housing HM is illustrated as including, but not necessarily limited to, first and second housings HM1, HM2 that are separate from each other. The electronic device ED may further include a hinge structure for connecting the first and second housings HM1, HM2.

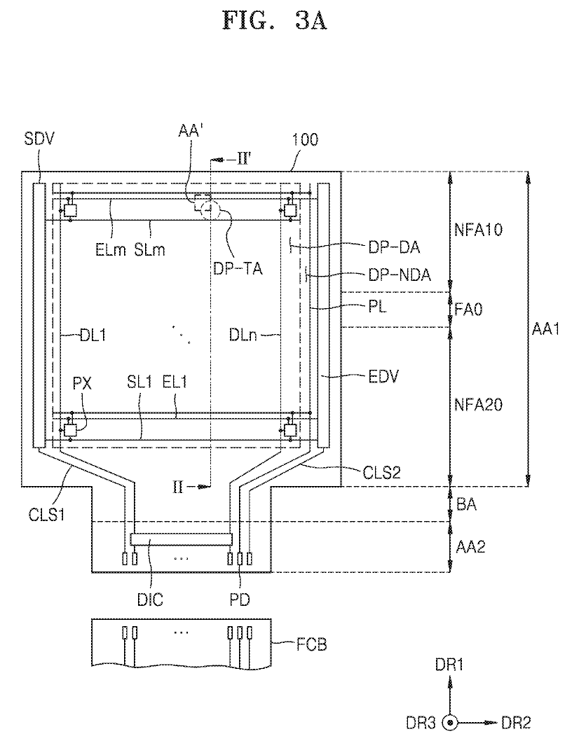

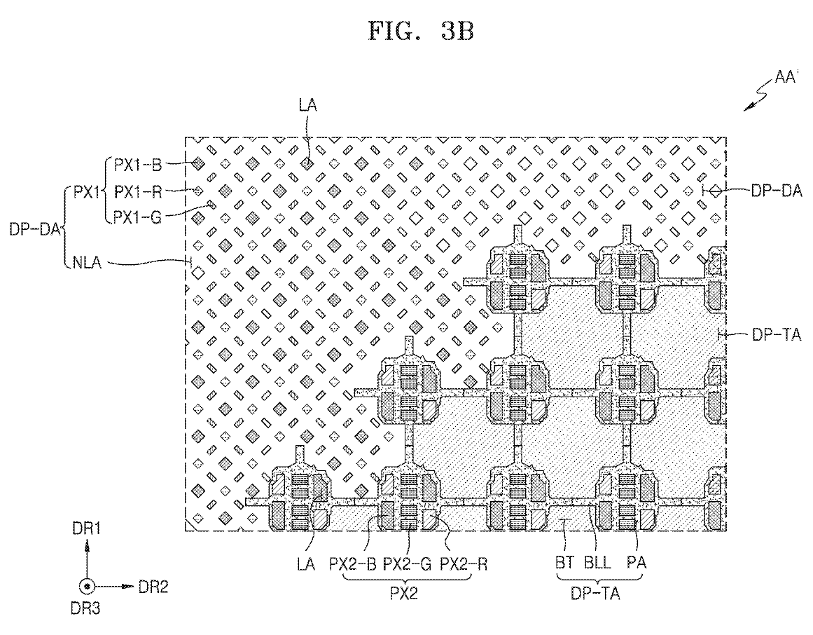

FIG. 3A is a plan view of a display panel according to an embodiment of the disclosure, and FIG. 3B is a plan view of a portion of the display panel according to an embodiment of the disclosure. FIG. 3B is a plan view that enlarges a portion of area AA’ of FIG. 3A.

Referring to FIG. 3A, the display panel DP may include a display area DP-DA and a non-display area DP-NDA surrounding the display area DP-DA. The display area DP-DA and non-display area DP-NDA are distinguished by the presence of pixels PX. Pixels PX are disposed in the display area DP-DA. A scan driver SDV, a data driver, and a light-emitting driver EDV may be disposed in the non-display area DP-NDA. The data driver may be some circuits configured in the driver chip DIC illustrated in FIG. 3A.

The display panel DP includes a first area AA1, a second area AA2, and a bending area BA divided in the first direction DR1. The second area AA2 and the bending area BA may be part of the non-display area DP-NDA. The bending area BA is located between the first area AA1 and the second area AA2.

The first area AA1 is an area corresponding to the display surface DS of FIG. 1A. The first area AA1 may include a first non-folding area NFA10, a second non-folding area NFA20, and a folding area FA0. The first non-folding area NFA10, the second non-folding area NFA20, and the folding area FA0 correspond to the first non-folding area NFA1, the second non-folding area NFA2, and the folding area FA of FIGS. 1A to 1C, respectively.

The lengths of the bending area BA and the second area AA2 within the first direction DR1 may be shorter than the length of the first area AA1. Areas with a shorter length along the bending axis may be bent more easily.

The display panel DP may include a plurality of pixels PX, a plurality of scan lines SL1 to SLm, a plurality of data lines DL1 to DLn, a plurality of light-emitting lines EL1 to ELm, first and second control lines CSL1 and CSL2, a power line PL, and a plurality of pads PD. Here, m and n are positive integers. Pixels PX may be connected to scan lines SL1 to SLm, data lines DL1 to DLn, and emission lines EL1 to ELm.

The injection lines SL1 to SLm may be extended in the second direction DR2 and connected to the injection driver SDV. Data lines DL1 to DLn extend in the first direction DR1 and may be connected to a driver chip DIC via a bending area BA. The light-emitting lines EL1 to ELm may be extended in the second direction DR2 and connected to the light-emitting driver EDV.

The power line PL may include a portion extending in the second direction DR2 and a portion extending in the first direction DR1. The portion extending in the first direction DR1 and the portion extending in the second direction DR2 may be disposed on different layers. A portion of the power line PL extending in the first direction DR1 may be extended to the second area AA2 via the bending area BA. The power line PL may provide the first voltage to the pixels PX.

The first control line CLS1 is connected to the injection driver SDV and may extend toward the bottom of the second area AA2 via the bending area BA. The second control line CLS2 is connected to the light-emitting driver EDV and may extend toward the bottom of the second area AA2 via the bending area BA.

On the plane, the pads PD may be disposed adjacent to the bottom of the second area AA2. The driver chip DIC, the power line PL, the first control line CLS1, and the second control line CLS2 may be connected to the pad's PDs. A flexible circuit board FCB may be electrically connected to pads PDs through an anisotropic conductive adhesive layer.

Referring to FIG. 3B, the sensing area DP-TA may be an area with higher light transmittance and lower resolution than the display area DP-DA. Light transmittance and resolution are measured within a reference area. The sensing area DP-TA has a smaller occupancy ratio of the shading structure within the reference area than the display area DP-DA. The shading structure may include a conductive pattern of a circuit layer described below, an electrode of a light-emitting element, a shading pattern, etc.

The sensing area DP-TA has a lower resolution within the reference area than the display area DP-DA. The sensing area DP-TA has a smaller number of pixels disposed within the reference area (or the same area) than the display area DP-DA.

As illustrated in FIG. 3B, a first pixel (PX1) may be disposed in the display area DP-DA, and a second pixel PX2 may be disposed in the sensing area DP-TA. The first pixel PX1 and the second pixel PX2 may have different light-emitting areas when comparing the areas of pixels of the same color. The first pixel PX1 and the second pixel PX2 may have different arrangements.

In FIG. 3B, the light-emitting areas LA of the first pixel PX1 and the second pixel PX2 are depicted as representing the first pixel PX1 and the second pixel PX2. Each of the light-emitting areas LA may be defined as an area where the anode of the light-emitting element is exposed from the pixel definition film. Non-light-emitting areas NLA are disposed between the emitting areas LA within the display area DP-DA.

The first pixel PX1 may include a first color pixel PX1-R, a second color pixel PX1-G, and a third color pixel PX1-B, and the second pixel PX2 may include a first color pixel PX2-R, a second color pixel PX2-G, and a third color pixel PX2-B. Each of the first pixel PX1 and the second pixel PX2 may include a red pixel, a green pixel, and a blue pixel.

The sensing area DP-TA may include a pixel area PA, a wiring area BLL, and a transmission area BT. The second pixel PX2 is disposed within the pixel area PA. It is illustrated that within a single pixel area PA, two first color pixels PX2-R, four second color pixels PX2-G, and two third color pixels PX2-B are disposed, but the disclosure is not necessarily limited to this configuration.

In the pixel area PA and the wiring area BLL, conductive patterns, signal lines, or light-shielding patterns related to the second pixel PX2 may be disposed. The shading pattern may be a metal pattern and may substantially overlap the pixel area PA and the wiring area BLL. The pixel area PA and the wiring area BLL may be opaque areas.

The transmission area BT is an area through which the optical signal actually passes. Since the second pixel PX2 is not disposed in the transmission area BT, a conductive pattern, a signal line, or a light-shielding pattern is disposed instead. Therefore, the transmission area BT increases the light transmittance of the sensing area DP-TA.

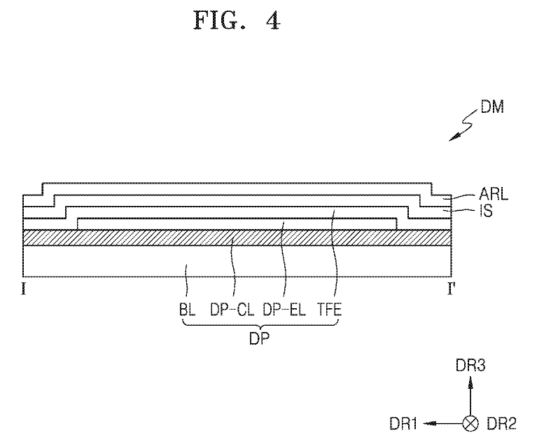

FIG. 4 is a cross-sectional view of a display module according to an embodiment of the present disclosure, for example, a cross-sectional view of an example of a display module cut along the I-I' line of FIG. 2A.

Referring to FIG. 4, the display module DM may include a display panel DP, an input sensor IS, and an anti-reflection layer ARL. The display panel DP may include a base layer BL, a circuit layer DP-CL, a light-emitting element layer DP-EL, and an encapsulation layer TFE.

The base layer BL may provide a base surface on which the circuit layer DP-CL is disposed. The base layer BL may be a flexible substrate capable of bending, folding, rolling, etc. to at least a noticeable extent without cracking or otherwise sustaining damage thereto. The base layer BL may be a glass substrate, a metal substrate, or a polymer substrate. However, the embodiment of the disclosure is not necessarily limited thereto, and the base layer BL may be an inorganic layer, an organic layer, or a composite material layer.

The base layer BL may have a multi-layer structure. For example, the base layer BL may include a first synthetic resin layer, a multi-layer or single-layer inorganic layer, and a second synthetic resin layer disposed on the multi-layer or single-layer inorganic layer. Each of the first and second synthetic resin layers may include a polyimide-based resin, but is not necessarily limited thereto.

The circuit layer DP-CL may be disposed on the base layer BL. The circuit layer DP-CL may include an insulating layer, a semiconductor pattern, a conductive pattern, and a signal line.

The light-emitting element layer DP-EL may be disposed on the circuit layer DP-CL. The light-emitting element layer DP-EL may include a light-emitting element. For example, the light-emitting element may include an organic light-emitting material, an inorganic light-emitting material, an organic-inorganic light-emitting material, a quantum dot, a quantum rod, a micro LED, or a nano LED.

The encapsulation layer TFE may be disposed on the light-emitting element layer DP-EL. The encapsulation layer TFE may protect the light-emitting element layer DP-EL from foreign substances such as moisture, oxygen, and dust particles. The encapsulation layer TFE may include at least one inorganic layer. The encapsulation layer TFE may include a laminated structure of inorganic layer/organic layer/inorganic layer.

The input sensor IS may be disposed directly on the display panel DP. The display panel DP and input sensor IS may be formed through a continuous process. Here, “directly disposed” may mean that no third component is disposed between the input sensor IS and the display panel DP. For example, a separate adhesive layer might not be disposed between the input sensor IS and the display panel DP.

An anti-reflection layer ARL may be disposed directly on the input sensor IS. An anti-reflection layer ARL may reduce the reflectance of external light incident from the outside of the display device DD. The anti-reflection layer ARL may include color filters. The color filters may have a preset arrangement. For example, the color filters may be disposed in consideration of the emission colors of pixels included in the display panel DP. In some embodiments, the anti-reflection layer ARL may further include a black matrix adjacent to the color filters.

In an embodiment of the disclosure, the positions of the input sensor IS and the anti-reflection layer ARL may be exchanged. In an embodiment of the disclosure, the anti-reflection layer ARL may be swapped with a polarizing film. The polarizing film may be bonded to the input sensor IS via an adhesive layer.

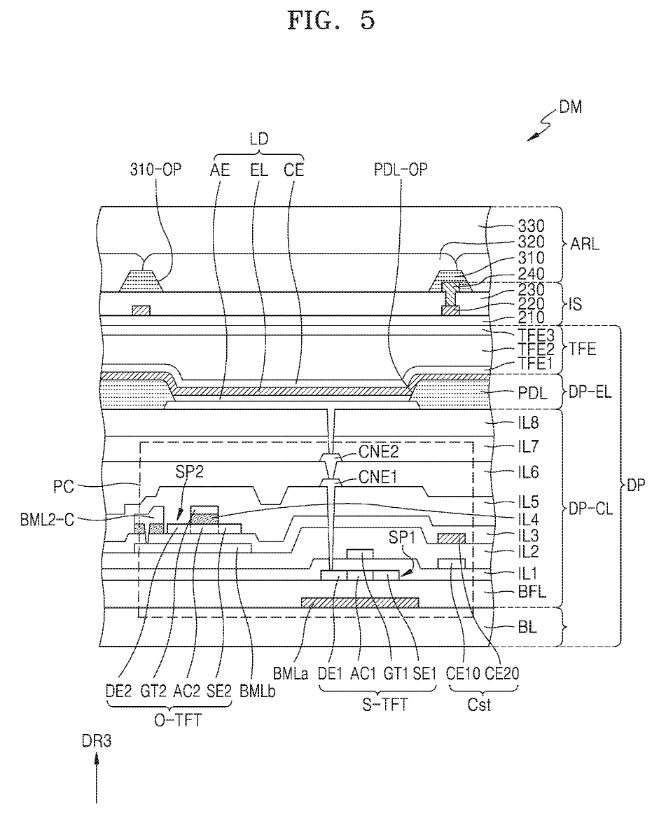

FIG. 5 is a cross-sectional view of a portion of a display module according to an embodiment of the disclosure. FIG. 5 illustrates a portion of the display module DM of an embodiment illustrated in FIG. 4 in more detail. For example, FIG. 5 illustrates in more detail the configurations corresponding to pixels of one of the display modules DM of an embodiment.

FIG. 5 illustrates a silicon transistor S-TFT and an oxide transistor O-TFT of a light-emitting element LD and a pixel circuit PC. At least one of the plurality of transistors included in the pixel circuit PC may be an oxide transistor O-TFT, and the remaining transistors may be silicon transistors S-TFT.

A buffer layer BFL may be disposed on the base layer BL. The buffer layer BFL may prevent metal atoms or impurities from diffusing from the base layer BL to the first semiconductor pattern SP1 on the upper side. The first semiconductor pattern SP1 includes an active area AC1 of a silicon transistor S-TFT. The buffer layer BFL may control the rate at which heat is provided during the crystallization process for forming the first semiconductor pattern SP1, thereby allowing the first semiconductor pattern SP1 to be formed uniformly.

A first back surface metal layer BMLa may be disposed under a silicon transistor S-TFT, and a second back surface metal layer BMLb may be disposed under an oxide transistor O-TFT. The first and second back surface metal layers BMLa, BMLb may overlap the pixel circuit PC. The first and second back surface metal layers BMLa, BMLb may block external light from reaching the pixel circuit PC.

The first back surface metal layer BMLa may correspond to at least a portion of the pixel circuit PC. The first back surface metal layer BMLa may overlap a driving transistor implemented as a silicon transistor S-TFT.

A first back surface metal layer BMLa may be disposed between the base layer BL and the buffer layer BFL. In an embodiment of the disclosure, an inorganic barrier layer may be further disposed between the first back surface metal layer BMLa and the buffer layer BFL. The first back surface metal layer BMLa may be connected to electrodes or wiring and may receive a voltage or a signal from them. According to an embodiment of the disclosure, the first back surface metal layer BMLa may be a floating electrode that is electrically isolated from other electrodes or wiring.

A second back surface metal layer BMLb may correspond to the lower portion of the oxide transistor O-TFT. A second back surface metal layer BMLb may be disposed between the second insulating layer IL2 and the third insulating layer IL3. The second back surface metal layer BMLb may be disposed on the same layer as the second electrode CE20 of the storage capacitor Cst. The second back surface metal layer BMLb is connected to the contact electrode BML2-C and may receive a constant voltage or a signal. The contact electrode BML2-C may be disposed on the same layer as the gate GT2 of the oxide transistor O-TFT.

Each of the first back surface metal layer BMLa and the second back surface metal layer BMLb may include a reflective metal. For example, each of the first back surface metal layer BMLa and the second back surface metal layer BMLb may include silver (Ag), an alloy containing silver (Ag), molybdenum (Mo), an alloy containing molybdenum, aluminum (Al), an alloy containing aluminum, aluminum nitride (AlN), tungsten (W), tungsten nitride (WN), copper (Cu), and p+ doped amorphous silicon. The first back surface metal layer BMLa and the second back surface metal layer BMLb may include the same material or may include different materials.

According to an embodiment of the disclosure, the second back surface metal layer BMLb may be omitted. The first back surface metal layer BMLa extends to the bottom of the oxide transistor O-TFT, so that the first back surface metal layer BMLa may block light incident on the bottom of the oxide transistor O-TFT.

The first semiconductor pattern SP1 may be disposed on a buffer layer BFL. The first semiconductor pattern SP1 may include a silicon semiconductor. For example, silicon semiconductors may include amorphous silicon, polycrystalline silicon, etc. For example, the first semiconductor pattern SP1 may include low-temperature polysilicon.

FIG. 5 illustrates a portion of the first semiconductor pattern SP1 disposed on the buffer layer BFL, and the first semiconductor pattern SP1 may be further disposed in other areas. The first semiconductor pattern SP1 may be disposed in accordance with a specific rule across the pixels. The first semiconductor pattern SP1 may have different electrical properties depending on whether it is doped. The first semiconductor pattern SP1 may include a first area having high conductivity and a second area having low conductivity. The first region may be doped with an N-type dopant or a P-type dopant. A P-type transistor may include a doped area doped with a P-type dopant, and an N-type transistor may include a doped area doped with an N-type dopant. The second area may be an undoped area or an area doped at a lower concentration than the first area.

The conductivity of the first area is greater than that of the second area, and the first area may substantially act as an electrode or a signal line. The second area may substantially correspond to the active area (or channel) of the transistor. For example, a part of the first semiconductor pattern SP1 may be an active area of the transistor, another part may be a source or drain of the transistor, and yet another part may be a connecting electrode or a connecting signal line.

A source area SE1 (also referred to as a source), an active area AC1 (also referred to as a channel), and a drain area DE1 (also referred to as a drain) of a silicon transistor (S-TFT) may be formed from a first semiconductor pattern SP1. The source area SE1 and the drain area DE1 may extend in opposite directions from the active area AC1 in the cross-section.

The first insulating layer IL1 may be disposed on the buffer layer BFL. The first insulating layer IL1 overlaps commonly with a plurality of pixels and may cover the first semiconductor pattern SP1. The first insulating layer IL1 may be an inorganic layer and/or an organic layer and may have a single-layer or multi-layer structure. The first insulating layer IL1 may include at least one of aluminum oxide, titanium oxide, silicon oxide, silicon nitride, silicon oxynitride, zirconium oxide, and hafnium oxide. In an embodiment, the first insulating layer IL1 may be a single-layer silicon oxide layer. The insulating layer of the circuit layer DP-CL described later as well as the first insulating layer IL1 may be an inorganic layer and/or an organic layer and may have a single-layer or multi-layer structure. The inorganic layer may include at least one of the materials described above but is not necessarily limited thereto.

The gate GT1 of the silicon transistor S-TFT is disposed on the first insulating layer IL1. The gate GT1 may be part of a metal pattern. The gate GT1 overlaps the active area AC1. In the process of doping the first semiconductor pattern SP1, the gate GT1 may function as a mask. The gate GT1 may include, but is not necessarily limited to, titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), indium zinc oxide (IZO), and the like.

The second insulating layer IL2 is disposed on the first insulating layer IL1 and may cover the gate GT1. The third insulating layer IL3 may be disposed on the second insulating layer IL2. The second electrode CE20 of the storage capacitor Cst may be disposed between the second insulating layer IL2 and the third insulating layer IL3. In some embodiments, the first electrode CE10 of the storage capacitor Cst may be disposed between the first insulating layer IL1 and the second insulating layer IL2.

The second semiconductor pattern SP2 may be disposed on the third insulating layer IL3. The second semiconductor pattern SP2 may include an active area AC2 of an oxide transistor O-TFT described later. The second semiconductor pattern SP2 may include an oxide semiconductor. The second semiconductor pattern SP2 may include a transparent conductive oxide (TCO) such as indium tin oxide (ITO), indium zinc oxide (IZO), indium gallium zinc oxide (IGZO), zinc oxide (ZnO), or indium oxide (In₂O₃).

An oxide semiconductor may include multiple areas that are distinguished by whether or not the transparent conductive oxide has been reduced. The area where the transparent conductive oxide is reduced (hereinafter, referred to as the reduced area) has greater conductivity than the area where it is not reduced (hereinafter, referred to as the non-reduced area). The reduction area essentially may act as the source/drain or signal line of the transistor. The non-reducing area essentially corresponds to the semiconductor area (or an active area or a channel) of the transistor. For example, some areas of the second semiconductor pattern SP2 may be semiconductor areas of the transistor, other areas may be source areas/drain areas of the transistor, and still other areas may be signal transmission areas.

The source area SE2 (also referred to as a source), active area AC2 (also referred to as a channel), and drain area DE2 (also referred to as a drain) of the oxide transistor O-TFT may be formed from the second semiconductor pattern SP2. The source area SE2 and the drain area DE2 may extend in opposite directions from the active area AC2 in the cross-section.

The fourth insulating layer IL4 may be disposed on the third insulating layer IL3. As illustrated in FIG. 5, the fourth insulating layer IL4 may be an insulating pattern that overlaps the gate GT2 of the oxide transistor O-TFT and exposes the source area SE2 and drain area DE2 of the oxide transistor O-TFT. As illustrated in FIG. 5, the fourth insulating layer IL4 may cover the second semiconductor pattern SP2.

As illustrated in FIG. 5, the gate GT2 of the oxide transistor O-TFT is disposed on the fourth insulating layer IL4. The gate GT2 of an oxide transistor O-TFT may be part of a metal pattern. The gate GT2 of the oxide transistor O-TFT overlaps the active area AC2.

The fifth insulating layer IL5 is disposed on the fourth insulating layer IL4 and may cover the gate GT2. The first connecting electrode CNE1 may be disposed on the fifth insulating layer IL5. The first connecting electrode CNE1 can be connected to the drain area DE1 of the silicon transistor S-TFT through a contact hole penetrating the first to fifth insulating layers IL1, IL2, IL3, IL4, IL5.

The sixth insulating layer IL6 may be disposed on the fifth insulating layer IL5. The second connecting electrode CNE2 may be disposed on the sixth insulating layer IL6. The second connecting electrode CNE2 may be connected to the first connecting electrode CNE1 through a contact hole penetrating the sixth insulating layer IL6. The seventh insulating layer IL7 is disposed on the sixth insulating layer IL6 and may cover the second connecting electrode CNE2. The eighth insulating layer IL8 may be disposed on the seventh insulating layer IL7.

Each of the sixth insulating layer IL6, the seventh insulating layer IL7, and the eighth insulating layer IL8 may be an organic layer. For example, each of the sixth insulating layer IL6, the seventh insulating layer IL7, and the eighth insulating layer IL8 may include a general-purpose polymer such as benzocyclobutene (BCB), polyimide, hexamethyldisiloxane (HMDSO), polymethylmethacrylate (PMMA), and polystyrene (PS), a polymer derivative having a phenol group, an acrylic polymer, an imide polymer, an aryl ether polymer, an amide polymer, a fluorinated polymer, a p-xylene polymer, a vinyl alcohol polymer, and blends thereof.

A light-emitting element LD may include a first electrode AE, a light-emitting layer EL, and a second electrode CE. The second electrode CE may be provided in common on a plurality of light-emitting elements.

The first electrode AE of the light-emitting element LD may be disposed on the eighth insulating layer IL8. The first electrode AE of the light-emitting element LD may be a transparent electrode, a semitransparent electrode, or a reflective electrode. According to an embodiment of the disclosure, each of the first electrodes AE of the light-emitting element LD may include a reflective layer formed of Ag, Mg, Al, Pt, Pd, Au, Ni, Nd, Ir, Cr or a compound thereof, and a transparent or semitransparent electrode layer formed on the reflective layer. The transparent or semitransparent electrode layer may include at least one selected from the group consisting of indium tin oxide (ITO), indium zinc oxide (IZO), indium gallium zinc oxide (IGZO), zinc oxide (ZnO) or indium oxide (In₂O₃), and aluminum doped zinc oxide (AZO). For example, the first electrode AE of the light-emitting element LD may include a laminated structure of ITO/Ag/ITO.

The pixel defining layer PDL may be disposed on the eighth insulating layer IL8. The pixel defining layer PDL may have light-absorbing properties. For example, the pixel defining layer PDL may have a black color. The pixel defining layer PDL may include a black coloring agent. Black ingredients may include black dye, black pigment. The black component may include carbon black, a metal such as chromium, or an oxide thereof. The pixel defining layer PDL may correspond to a shading pattern having shading properties.

The pixel defining layer PDL may cover a portion of the first electrode AE of the light-emitting element LD. For example, an opening PDL-OP that exposes a portion of the first electrode AE of the light-emitting element LD may be defined in the pixel defining layer PDL. The pixel defining layer PDL may increase the distance between the edge of the first electrode AE and the second electrode CE of the light-emitting element LD. Therefore, it may play a role in preventing arcs, etc. from occurring at the edge of the first electrode AE by the pixel defining layer PDL.

A hole control layer may be disposed between the first electrode AE and the light-emitting layer EL. The hole control layer includes a hole transport layer and may further include a hole injection layer. An electronic control layer may be disposed between the light-emitting layer EL and the second electrode CE. The electron control layer includes an electron transport layer and may further include an electron injection layer. The hole control layer and the electron control layer can be formed commonly for a plurality of pixels PX (see FIG. 3A) using an open mask.

The encapsulation layer TFE may be disposed on the light-emitting element layer DP-EL. The encapsulation layer TFE may include an inorganic layer TFE1, an organic layer TFE2, and an inorganic layer TFE3 that are sequentially laminated, but the layers constituting the encapsulation layer are not necessarily limited thereto.

The inorganic layers TFE1, TFE3 can protect the light-emitting element layer DP-EL from moisture and oxygen, and the organic layer TFE2 can protect the light-emitting element layer DP-EL from foreign substances such as dust particles. The inorganic layers TFE1, TFE3 may include a silicon nitride layer, a silicon oxynitride layer, a silicon oxide layer, a titanium oxide layer, or an aluminum oxide layer. The organic layer TFE2 may include an acrylic-based organic layer but is not necessarily limited thereto.

The input sensor IS may be disposed on the display panel DP. The input sensor IS may be referred to as a sensor, an input sensing layer, or an input sensing panel. The input sensor IS may include a sensor base layer 210, a first conductive layer 220, a detection insulating layer 230, and a second conductive layer 240.

The sensor base layer 210 can be disposed directly on the display panel DP. The sensor base layer 210 may be an inorganic layer including at least one of silicon nitride, silicon oxynitride, and silicon oxide. Alternatively, the sensor base layer 210 may be an organic layer including epoxy resin, acrylic resin, or imide series resin. The sensor base layer 210 may have a single-layer structure or a multi-layer structure laminated along the third direction DR3.

Each of the first conductive layer 220 and the second conductive layer 240 may have a single-layer structure or a multi-layer structure laminated along the third direction DR3. The first conductive layer 220 and the second conductive layer 240 may include conductive lines defining mesh-shaped sensing electrodes. The challenge lines might not overlap the opening PDL-OP and may overlap the pixel defining layer PDL.

The conductive layer of the single-layer structure may include a metal layer or a transparent conductive layer. The metal layer may include molybdenum, silver, titanium, copper, aluminum, or alloys thereof. The transparent conductive layer may include a transparent conductive oxide, such as indium tin oxide (ITO), indium zinc oxide (IZO), zinc oxide (ZnO), or indium zinc tin oxide (IZTO). In addition, the transparent conductive layer may include a conductive polymer such as PEDOT, metal nanowires, graphene, etc.

The multilayer conductive layer may include sequentially laminated metal layers. The metal layers may, for example, have a three-layer structure of titanium/aluminum/titanium. The multilayer conductive layer may include at least one metal layer and at least one transparent conductive layer.

The detection insulating layer 230 may be disposed between the first conductive layer 220 and the second conductive layer 240. The detection insulating layer 230 may include an inorganic film. The inorganic film may include at least one of aluminum oxide, titanium oxide, silicon oxide, silicon nitride, silicon oxynitride, zirconium oxide, and hafnium oxide.

Alternatively, the detection insulating layer 230 may include an organic film. The organic film may include at least one of an acrylic resin, a methacrylic resin, a polyisoprene, a vinyl resin, an epoxy resin, a urethane resin, a cellulose resin, a siloxane resin, a polyimide resin, a polyamide resin, and a perylene resin.

The anti-reflection layer ARL may be disposed over the input sensor IS. The anti-reflection layer ARL may include a division layer 310, a plurality of color filters 320, and a flattening layer 330.

The material constituting the division layer 310 is not necessarily limited as long as it is a material that absorbs light. The division layer 310 is a layer having a black color, and in an embodiment, the division layer 310 may include a black component (black coloring agent). Black ingredients may include black dye, black pigment. The black component may include carbon black, a metal such as chromium, or their oxides.

The division layer 310 may cover the second conductive layer 240 of the input sensor IS. The division layer 310 may prevent external light reflection caused by the second conductive layer 240. In some areas of the display module DM, the division layer 310 may be omitted. The transmittance of the area where the division layer 310 is omitted and not disposed may be higher compared to that of other areas.

An opening 310-OP may be defined in the division layer 310. The opening 310-OP may overlap with the first electrode AE of the light-emitting element LD. Any one of a plurality of color filters 320 may overlap the first electrode AE of the light-emitting element LD. Any one of a plurality of color filters 320 may cover the opening 310-OP. Each of a plurality of color filters 320 may be in contact with the division layer 310.

The flattening layer 330 may cover the division layer 310 and a plurality of color filters 320. The flattening layer 330 may include an organic material and may provide a flat surface on the upper surface of the flattening layer 330. In an embodiment of the disclosure, the flattening layer 330 may be omitted.

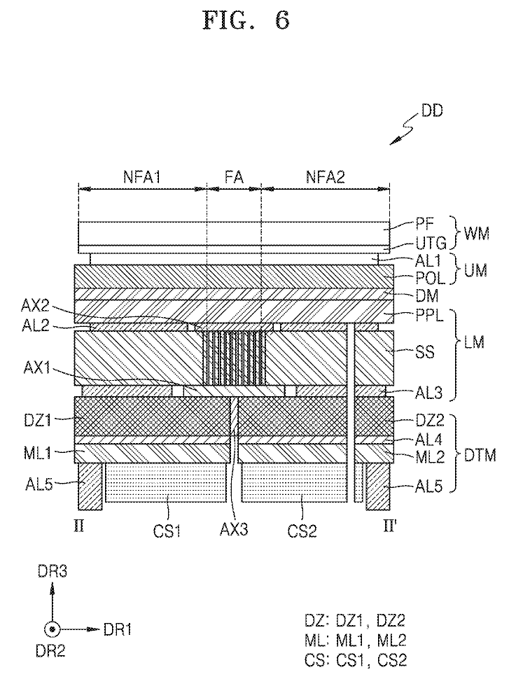

FIG. 6 is a side view of an example display device cut along the line II-II' of FIG. 3A.

Referring to FIG. 6, a display device DD, according to an embodiment, may include a window WM, an upper member UM, a display module DM, a lower member LM, and a plate module DTM. The upper member UM generally refers to a configuration disposed between the window WM and the display module DM, the lower member LM generally refers to a configuration disposed between the display module DM and the plate module DTM, and the plate module DTM generally refers to a configuration disposed under the lower member LM.

The display device DD may specifically include a window protective layer PF, a thin film glass substrate UTG, a first adhesive layer AL1, a polarizer POL, a display module DM, a lower protective film PPL, a second adhesive layer AL2, a panel support SS, a third adhesive layer AL3, a plate DZ, a fourth adhesive layer AL4, a metal layer ML, a buffer CS, and a fifth adhesive layer AL5. In the claim, one side of the third direction DR3 may be expressed as upper, and the other side of the third direction DR3 may be expressed as lower based on one component.

For example, the display device DD may include a display panel DP including a first non-folding area NFA1, a second non-folding area NFA2, and a folding area FA disposed between the first non-folding area NFA1 and the second non-folding area NFA2, a lower member LM disposed on a lower side of the display panel DP, and a plate module DTM disposed on a lower side of the lower member LM. The lower member LM may include a panel support SS overlapping at least the first non-folding area NFA1 and the second non-folding area NFA2.

The first non-folding area NFA1, the folding area FA, and the second non-folding area NFA2 of the display device (DD) may be equally applied to the display device DD, for example, the above-described window protective layer PF, the thin film glass substrate UTG, the first adhesive layer AL1, the display module DM, the lower protective film PPL, the second adhesive layer AL2, the panel support SS, the third adhesive layer AL3, the plate DZ, the fourth adhesive layer AL4, the metal layer ML, and the buffer CS. For example, a portion of the display module DM that overlaps the first non-folding area NFA1 of the display device DD in the third direction DR3 may become the first flat portion of the display module DM, a portion of the display module DM that overlaps the folding area FA of the display device DD in the third direction DR3 may become the first bending portion of the display module DM, and a portion of the display module DM that overlaps the second non-folding area NFA2 of the display device DD may become the second flat portion of the display module DM.

Likewise, the first display area DA1, the first non-display area NDA1, the second display area DA2 and the second non-display area NDA2 of the display device DD may be equally applied to the above-described window protective layer PF, the thin film glass substrate UTG, the first adhesive layer AL1, the display module DM, the lower protective film PPL, the second adhesive layer AL2, the panel support SS, the third adhesive layer AL3, the plate DZ, the metal layer ML and the buffer CS.

The window protective layer PF may perform at least one of the following functions: preventing scattering, absorbing shock, preventing scratches, preventing fingerprints, and preventing glare of the thin film glass substrate UTG. A window protective layer PF may be disposed on one side (hereinafter referred to as the “upper surface”) of a thin film glass substrate UTG in the third direction DR3. The window protective layer PF may be attached to the upper surface of the thin film glass substrate UTG via an adhesive agent, such as a pressure-sensitive adhesive.

The thin film glass substrate UTG may play a role in protecting the display module DM, which will be described later, from the outside. The thin film glass substrate UTG may be disposed on one side (hereinafter referred to as the “upper surface”) of the polarizer POL in the third direction DR3. The thin film glass substrate UTG is made of a transparent material, such as glass or plastic. For example, the thin film glass substrate UTG member 200 may be an ultra-thin glass having a thickness of 0.1mm or less or a transparent polyimide film.

The thin film glass substrate UTG may be attached to the upper surface of the polarizer POL by the first adhesive layer AL1. The first adhesive layer AL1 may be a transparent adhesive film or a transparent adhesive resin.

The polarizer POL may polarize light emitted from the display module DM or polarize light incident on the display module DM. The polarizer POL may be disposed on one side (hereinafter referred to as the "top surface") of the display module DM in the third direction DR3.

The polarizer POL may be omitted depending on the embodiment. When the polarizer POL is omitted, the thin film glass substrate UTG may be attached to the upper surface of the display module DM by the first adhesive layer AL1.

The display module DM is a panel that displays a screen, and any type of display module DM, such as an organic light-emitting display module DM including an organic light-emitting layer, an ultra-small light-emitting diode display module DM using a micro LED, a quantum dot light-emitting display module DM using a quantum dot light-emitting element including a quantum dot light-emitting layer, or an inorganic light-emitting display module DM using an inorganic light-emitting element including an inorganic semiconductor, may be applied as the display module DM of the present embodiment. Based on FIGS. 1A-1C, the display module DM may display the screen in one direction DR3.

The lower protective film PPL may support the display module DM and protect a lower surface of the display module DM. The lower protective film PPL may be disposed on the other side (hereinafter referred to as the “bottom side”) of the third direction DR3 of the display module DM. The lower protective film PPL may be plastic such as polyethylene terephthalate or polyimide.

The panel support SS may support the lower surface of the display module DM. The panel support SS may be disposed on another surface of the lower protective film PPL in the third direction DR3 (hereinafter referred to as the "bottom surface"). The panel support SS may be a rigid member whose shape or volume does not easily change due to external pressure.

The panel support SS may include a grid pattern that overlaps the folding area FA so as to be easily bent in the folding area FA.

The third adhesive layer AL3 may be disposed on the lower surface of the panel support SS. The third adhesive layer AL3 may include a pressure-sensitive adhesive. When the adhesive includes a pressure-sensitive adhesive, the adhesion of the adhesive to the panel support SS and/or plate DZ may be increased when pressure is applied to the adhesive. For example, after placing the third adhesive layer AL3 including a pressure-sensitive adhesive between the panel support SS and the plate DZ, pressure may be applied to adhere the panel support SS and the plate DZ through the adhesive.

The pressure-sensitive adhesive included in the third adhesive layer AL3 may include a natural rubber adhesive, a styrene/butadiene latex-based adhesive, an ABA block copolymer type thermoplastic rubber (wherein A is a thermoplastic polystyrene end block and B is a middle block of polyisoprene rubber, polybutadiene rubber, polyethylene rubber or polybutylene rubber), an acrylic polymer adhesive such as butyl rubber, polyisobutylene, polyacrylate, a vinyl acetate/acrylic ester copolymer, and a vinyl ether polymer adhesive such as polyvinyl methyl ether, polyvinyl ethyl ether, and polyvinyl isobutyl ether.

The thickness of the third adhesive layer AL3 may be 15 μm or less. For example, the thickness of the third adhesive layer AL3 may be, but is not necessarily limited to, 10μm.

The plate DZ may include the first plate DZ1 and the second plate DZ2. The first plate DZ1 and the second plate DZ2 may be disposed on the lower surface of the panel support SS. The first plate DZ1 and the second plate DZ2 may be attached to the lower surface of the panel support SS by the third adhesive layer AL3 as described above.

The first plate DZ1 and the second plate DZ2 might not be disposed in the folding area FA to reduce the folding stress of the display device DD. The first plate DZ1 may overlap the first non-folding area NFA1, and the second plate DZ2 may overlap the second non-folding area NFA2. The gap between the first plate DZ1 and the second plate DZ2 overlaps the folding area FA and may be smaller than the width of the folding area FA in the first direction DR1.

The plate DZ may support the lower surface of the display module DM like the panel support SS and may be a rigid member whose shape or volume is not easily changed by external pressure. For example, the plate DZ may have the same function as the panel support SS at the bottom of the panel support SS and may be composed of the same material.

In an optional embodiment, if the plate DZ does not function as a panel support SS it may function as a digitizer. Alternatively, the plate DZ may function as a digitizer while simultaneously functioning as a panel support SS.

When the plate DZ functions as a digitizer, the plate DZ may include electrode patterns for detecting the approach or contact of an electronic pen/stylus, such as a pen/stylus supporting electromagnetic induction. The first plate DZ1 and the second plate DZ2 may detect a magnetic field or electromagnetic signal emitted from the electronic pen/stylus based on the electrode patterns and determine the point where the detected magnetic field or electromagnetic signal is the largest as the touch coordinate.

Magnetic metal powder may be disposed on the lower surface of the first plate DZ1 and the lower surface of the second plate DZ2. In this case, a magnetic field or electromagnetic signal passing through the first plate DZ1 and the second plate DZ2 may flow into the interior of the magnetic metal powder. Therefore, due to the magnetic metal powder, the magnetic field or electromagnetic signal of the first plate DZ1 and the second plate DZ2 may be reduced from being emitted to the lower surface of the display device DD.

A fourth adhesive layer AL4 may be disposed on the lower surface of the plate DZ. For example, the fourth adhesive layer AL4 may be disposed on the lower surface of the first plate DZ1 and the lower surface of the second plate DZ2 to cover the lower surface of the first plate DZ1 and the lower surface of the second plate DZ2. The fourth adhesive layer AL4 may fill the space between the plate DZ and the metal layer ML to maximize the bonding area between the plate DZ and the metal layer ML, and may play a role in physically fixing the plate DZ and the metal layer ML.

The fourth adhesive layer AL4 may be made of substantially the same material as the third adhesive layer AL3 described above. Therefore, to the extent that an element is not described in detail with respect to this figure, it may be understood that the element is at least similar to a corresponding element that has been described elsewhere within the present disclosure.

The thickness of the fourth adhesive layer AL4 may be 15μm or less. For example, the thickness of the third adhesive layer AL3 may be, but is not necessarily limited to, 13μm.

The metal layer ML may serve to support the plate DZ. The metal layer ML may include a first metal layer ML1 and a second metal layer ML2. The first metal layer ML1 may be disposed on the other side (hereinafter referred to as the ‘bottom side’) of the first plate DZ1 in the third direction DR3, and the second metal layer ML2 may be disposed on the other side (hereinafter referred to as the ‘bottom side’) of the second plate DZ2 in the third direction DR3.

The first metal layer ML1 and the second metal layer ML2 might not overlap in the folding area FA to reduce folding stress of the display device DD. For example, the first metal layer ML1 may overlap the first non-folding area NFA1, and the second metal layer ML2 may overlap the second non-folding area NFA2. The gap between the first metal layer ML1 and the second metal layer ML2 overlaps the folding area FA and may be smaller than the width of the folding area FA in the first direction DR1.

The first metal layer ML1 and the second metal layer ML2 may include a material having high rigidity. For example, the first metal layer ML1 and the second metal layer ML2 may include stainless steel such as SUS316 or copper Cu.

The buffer CS may include a first buffer CS1 and a second buffer CS2. The first buffer CS1 and the second buffer CS2 absorb external impacts and prevent the panel support SS and plate DZ members from being damaged. The first buffer CS1 and the second buffer CS2 may each include an elastic material such as rubber, a urethane-based material, or a foam-molded sponge made of an acrylic-based material.

The first buffer CS1 may be disposed on the lower surface of the first metal layer ML1, and the second buffer CS2 may be disposed on the lower surface of the second metal layer ML2. The first buffer CS1 and the second buffer CS2 might not be disposed in the folding area FA to reduce the folding stress of the display device DD. The first buffer CS1 may be disposed in the first non-folding area NFA1, and the second buffer CS2 may be disposed in the second non-folding area NFA2. The gap between the first buffer CS1 and the second buffer CS2 overlaps the folding area FA and may be smaller than the width of the folding area FA in the first direction DR1.

The fifth adhesive layer AL5 may serve to prevent moisture or dust from penetrating into the display device DD. The fifth adhesive layer AL5 may be disposed on the other side (hereinafter referred to as the ‘bottom side’) in the third direction DR3 of the first metal layer ML1 and the other side (hereinafter referred to as the ‘bottom side’) in the third direction DR3 of the second metal layer ML2. The fifth adhesive layer AL5 may be disposed at the edge of the first metal layer ML1 and the edge of the second metal layer ML2. The fifth adhesive layer AL5 may be disposed to surround the first buffer CS1 and the second buffer CS2. The fifth adhesive layer AL5 may include a waterproof tape or waterproof member that attaches the upper surface of the frame to the lower surface of the first metal layer ML1 and the lower surface of the buffer CS.

The fifth adhesive layer AL5 may overlap the magnet for maintaining the second state of the display device DD in the third direction DR3 without surrounding the first buffer CS1 and the second buffer CS2. In this case, the fifth adhesive layer AL5 may act as a magnetic shielding member capable of shielding magnetism to prevent the plate DZ member or the display module DM from being affected by the magnetism of the magnet.

In addition to the above-described configurations, the display device DD may have a protective member disposed in the folding area FA to improve impact resistance and crease phenomenon of the folding area FA. By arranging an auxetic structure, for example an auxetic structure made of foam material, the protective member may improve the impact absorption, rigidity, and tensile restoring power of the folding area FA.

Auxetic structures are materials or structures that have a negative Poisson’s ratio. Poisson’s ratio is a physical property that indicates the extent to which a material expands or contracts in the vertical direction when it is stretched or compressed.

For example, unlike general materials that have a positive Poisson’s ratio, which causes the material to shrink in the vertical direction when stretched in one direction, an auxetic structure refers to a material that expands or compresses in the vertical direction when stretched or compressed in one direction.

These properties of the auxetic structure allow it to be utilized as a shock absorbing material, etc., as it may uniformly expand or contract and absorb more energy when deformed by an external force.

The following provides a detailed description of the display device DD incorporating an auxetic structure.

A display device DD may include a display module DM comprising a first non-folding area NFA1 and a second non-folding area NFA2 disposed at least in the first direction DR1, and a folding area FA disposed between the first non-folding area NFA1 and the second non-folding area NFA2. In some embodiments, it may include a panel support SS disposed under the display module DM, and a plate DZ disposed under the panel support SS.

A first auxetic structure AX1 having a negative Poisson’s ratio may be disposed between the panel support SS and the plate DZ at least in the folding area FA. For example, the first auxetic structure AX1 may prevent sagging of the panel support SS. An area of the edge along the first direction DR1 of the first auxetic structure AX1 may also be disposed in the non-folding areas NFA1 and NFA2.

The first auxetic structure AX1 may be disposed on the same layer as the third adhesive layer AL3. For example, the first auxetic structure AX1 may be disposed between the third adhesive layer AL3 disposed in each of the first non-folding area NFA1 and the second non-folding area NFA2.

However, when the first auxetic structure AX1 is disposed in contact with the third adhesive layer AL3, it may extend in the folding direction due to its negative Poisson's ratio when the display device (DD) is folded, and consequently, it may also extend in the vertical direction. Due to this, the display module DM may be subjected to pressure, so that the first auxetic structure AX1 and the third adhesive layer AL3 may be spaced apart from each other.

The first auxetic structure AX1 may include a material having an elasticity whose length may be varied according to the folding and unfolding operation of the display device DD.

The first auxetic structure AX1 may include auxetic foam. Auxetic foam may be a porous structure having a negative Poisson’s ratio.

Auxetic foam is as good at absorbing shock as regular foam. In addition, unlike conventional foam, auxetic foam has a negative Poisson’s ratio due to its structure, which allows it to disperse impact and have high strength. For example, auxetic foam has high mechanical strength and compressive strength and has good energy absorption properties.

As an example, the first auxetic structure AX1 may include at least one of urethane, expanded polytetrafluoroethylene (ePTFE), for example, GORE-TEX, polyvinyl chloride (PVC), polymethacrylimide (PMI), or low-density polyethylene (LDPE). For example, the first auxetic structure AX1 may be a foam-type material having a micro-pattern formed through a thermo-compression and foaming process, using at least one of urethane, ePTFE, PVC, PMI, or LDPE. For example, the auxetic foam may include at least one of urethane, ePTFE, PVC, PMI or LDPE.

The first auxetic structure (AX1) may include a first stretchable pattern. Auxetic foam may include a stretchable pattern. For example, the first auxetic structure AX1 of the foam type may form a first stretchable pattern.

A stretchable pattern is a pattern designed so that a material may stretch or compress, and thus may have flexibility and elasticity. A stretchable pattern uses a specific type of spiral or repeating structure so that the pattern may expand or contract proportionally when the material is stretched. For example, a stretchable pattern has excellent tensile and resilient properties.

The stretchable pattern may control the aperture ratio of the stretchable pattern by adjusting the line width and pitch. For example, the thicker the line width and the smaller the pitch, the smaller the aperture ratio of the stretchable pattern may be.

When the first auxetic structure AX1 is unfolded, the aperture ratio of the first stretchable pattern may be adjusted to be low to prevent penetration of external foreign substances and moisture into the display module DM. As an example, when the first auxetic structure AX1 is unfolded, the aperture ratio of the first auxetic structure AX1, for example, the aperture ratio of the first stretchable pattern, may be 10% or less.

The first auxetic structure AX1 is formed of an auxetic foam-type material and has excellent shape recovery and elongation due to the soft properties of the foam even when folded. However, due to the auxetic properties having a negative Poisson’s ratio, its strength is increased when compressed, thereby improving impact resistance and reducing the creasing phenomenon.

In addition, the first auxetic structure AX1 may have improved tensile strength and resilience when folded by forming the auxetic foam into a stretchable pattern.

The display device DD may further include, in addition to the first auxetic structure AX1, the second auxetic structure AX2 disposed between the panel support SS and the display module DM in the folding area FA.

The second auxetic structure AX2 may be specifically disposed between the lower protective film PPL and the plate DZ. The second auxetic structure AX2 having a negative Poisson’s ratio may prevent sagging of the display module DM. An area of the edge along the first direction DR1 of the second auxetic structure AX2 may also be disposed in the non-folding areas NFA1 and NFA2.

The second auxetic structure AX2 may be disposed on the same layer as the second adhesive layer AL2. For example, the second auxetic structure AX2 may be disposed between the second adhesive layer AL2 disposed in each of the first non-folding area NFA1 and the second non-folding area NFA2.

However, in the case where the second auxetic structure AX2 is disposed in contact with the second adhesive layer AL2, when the display device DD is folded, the second auxetic structure AX2 having a negative Poisson’s ratio may elongate in the direction of folding and may also elongate in its vertical direction. Due to this, the display module DM may be subjected to pressure, so that the second auxetic structure AX2 and the second adhesive layer AL2 may be spaced apart from each other.

The second auxetic structure AX2 may include a material having an elasticity whose length may be varied according to the folding and unfolding operation of the display device DD.

Like the first auxetic structure AX1, the second auxetic structure AX2 may include an auxetic foam. As an example, the second auxetic structure AX2 may include at least one of urethane, ePTFE, PVC, PMI or LDPE. As an example, the second auxetic structure AX2 may be made of the same material as the first auxetic structure and may be formed into a foam type through the same or similar process.

The second auxetic structure AX2 may include a second stretchable pattern. Auxetic foam may include a stretchable pattern. For example, the second auxetic structure AX2 of the foam type may form a second stretchable pattern. The second stretchable pattern of the second auxetic structure AX2 may be the same as or different from the first stretchable pattern of the first auxetic structure AX1.

When the second auxetic structure AX2 is unfolded, the aperture ratio of the stretchable pattern may be adjusted low to prevent penetration of external foreign substances and moisture into the display module DM. As an example, the aperture ratio of the unfolded stretchable pattern of the second auxetic structure AX2 may be 10% or less.

For example, the second auxetic structure AX2, like the first auxetic structure AX1, has excellent restoring and elongation properties, has high strength, improves impact resistance, and may reduce the creasing phenomenon.

The display device DD may further include, in addition to the first plate DZ1 and second plate DZ2 disposed in the first direction DR1 and the first auxetic structure AX1, a third auxetic structure AX3 disposed between the first plate DZ1 and the second plate DZ2.

The third auxetic structure AX3 having a negative Poisson’s ratio may be specifically attached to the first plate DZ1 or the second plate DZ2 in the folding area FA. As an example, the thickness of the third auxetic structure AX3 may be equal to the thickness of the plate DZ.

The third auxetic structure AX3 may, like the first auxetic structure AX1, include an auxetic foam. As an example, the third auxetic structure AX3 may include at least one of urethane, ePTFE, PVC, PMI or LDPE. As an example, the third auxetic structure AX3 may be made of the same material as the first auxetic structure AX1 and may be formed into a foam type through the same or similar process.

For example, the third auxetic structure AX3 has high strength and increased impact resistance, just like the first auxetic structure AX1, and may reduce the creasing phenomenon.

The plate module DTM of the display device DD might not have the plate DZ. The fourth adhesive layer AL4 may also be absent, and a configuration of a lower member LM other than the plate DZ may be disposed under the lower member LM. As an example, a metal layer ML may be disposed under the lower member LM.

In the case where there is no plate DZ in the plate module DTM, the third auxetic structure AX3 between the first plate DZ1 and the second plate DZ2 also does not exist. However, the first auxetic structure AX1 might not exist, or the first auxetic structure AX1 may exist and a configuration of a lower member LM other than the plate DZ may be disposed under the first auxetic structure AX1 in the unfolding mode of the display device DD.

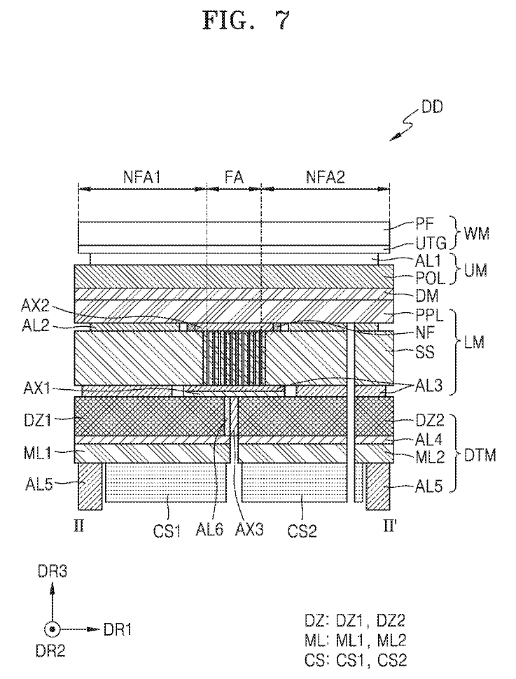

FIG. 7 is a side view of an example display device taken along line II-II’ of FIG. 3A.

Referring to FIG. 7, the display device DD may further include, in addition to the configuration described in FIG. 6, a buffer NF, the third adhesive layer AL3 between the first auxetic structure AX1 and the panel support SS, and/or the sixth adhesive layer.

The second auxetic structure AX2 along the first direction DR1 may further include a buffer NF having a positive Poisson’s ratio at the edge thereof. The buffer NF may be disposed in the same layer as the second adhesive layer AL2, similar to the second auxetic structure AX2.

The buffer NF may protect the second auxetic structure AX2. The buffer NF may be attached to the second auxetic structure AX2 as an example and might not be attached to the second adhesive layer AL2. The buffer NF may be attached to the second adhesive layer AL2 as an example and might not be attached to the second auxetic structure AX2.

The first auxetic structure AX1 is disposed on the first plate DZ1 and the second plate DZ2. When the display device DD is folded, a gap between the first plate DZ1 and the second plate DZ2 is created, so that the third adhesive layer AL3 may be further disposed between the first auxetic structure AX1 and the panel support SS to ensure structural stability of the first auxetic structure AX1.

Due to this, even when the display device DD is folded, the first auxetic structure AX1 remains stably attached to the panel support SS, and a display device DD with excellent restoration and elongation, high strength, increased impact resistance, and reduced creasing phenomenon can be produced.

The third auxetic structure AX3 is disposed between the first plate DZ1 and the second plate DZ2 when the display device DD is unfolded. Since the first plate DZ1 and the second plate DZ2 are separated when the display device DD is folded, the third auxetic structure AX3 may be attached to the first plate DZ1 or the second plate DZ2. At this time, the third auxetic structure AX3 may be attached to the first plate DZ1 or the second plate DZ2 by the sixth adhesive layer AL6.

The plate DZ is divided into the first plate DZ1 and the second plate DZ2, and since the first auxetic structure AX1 and the second auxetic structure AX2 protect the display module DM and the panel support SS and have excellent elastic restoring force, the third auxetic structure AX3 may be attached to either the first plate DZ1 or the second plate DZ2.

When the third auxetic structure AX3 is attached to both the first plate DZ1 and the second plate DZ2, the third auxetic structure AX3 may also have a structure that includes a stretchable pattern to enhance the elongation recovery force.

The display device DD, according to an embodiment, may be applied to various electronic devices ED. An electronic device ED, according to an embodiment, includes the display device DD described above, and may further include a module or device having additional functions in addition to the display device DD.

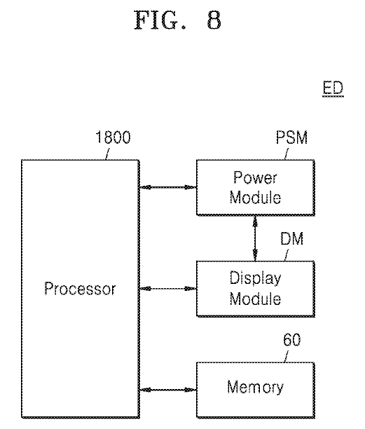

FIG. 8 is a block diagram of an electronic device according to an embodiment of the disclosure. Referring to FIG. 8, an electronic device ED, according to an embodiment, may include a display module DM, a processor 1800, a memory 60, and a power module PSM.

The processor 1800 may include at least one of a central processing unit (CPU), an application processor (AP), a graphic processing unit (GPU), a communication processor (CP), an image signal processor (ISP), and a controller.

Data information necessary for the operation of the processor 1800 or the display module DM may be stored in the memory 60. When the processor 1800 executes an application stored in the memory 60, an image data signal and/or an input control signal is transmitted to the display module DM, and the display module DM may process the received signal and output image information through the display screen.

A power module PSM may include a power supply module, such as a power adapter or a battery device, and a power conversion module that converts power supplied by the power supply module to generate power required for the operation of the electronic device ED.

At least one of the components of the above-described electronic device ED may be included in the display device DD according to the above-described embodiments. In some embodiments, some of the individual modules functionally included within a module may be included within the display device, while others may be provided separately from the display device. For example, the display device DD may include a display module DM, and the processor 1800, memory 60, and power module PSM may be provided in the form of other devices within the electronic device ED rather than within the display device DD.

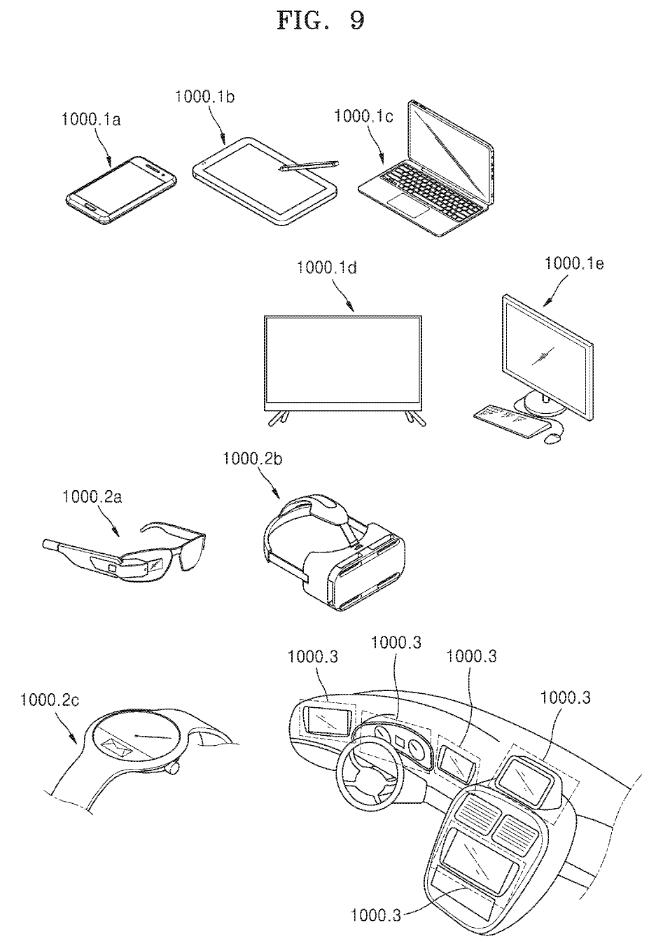

FIG. 9 is a schematic diagram of an electronic device according to various embodiments.

Referring to FIG. 9, various electronic devices to which the display device DD according to embodiments is applied may include not only image display electronic devices such as a smart phone 1000.1A, a tablet computer 1000.1B, a laptop/notebook computer 1000.1C, a TV 1000.1D, a computer monitor 1000.1E, but also wearable electronic devices including display modules such as smart glasses 1000.2A, a head mounted display 1000.2B, a smart watch 1000.2C, and vehicle electronic devices 1000.3 including display modules such as a car instrument panel, a center fascia, a dashboard-mounted center information display (CID), and a room mirror display.

According to an embodiment of the disclosure, by arranging an auxetic foam having a negative Poisson ratio in a folding area, a display device with increased impact absorption and tensile recovery in the folding area, as well as an electronic device including the same, can be realized.

Each of the embodiments described above may be implemented independently, but it goes without saying that the structure of each embodiment may be applied in combination to other embodiments.

Although the disclosure has been described with reference to the embodiments shown in the drawings, these are exemplary, and those skilled in the art will understand that various modifications and other equivalent embodiments are possible based on this disclosure.

The specific implementations described in the examples may be illustrative and do not necessarily limit the scope of the examples. In some embodiments, a component might not be necessarily required for the application of the disclosure.

The use of the term “above” and similar referential terms in the specification of embodiments (especially in the claims) may refer to both the singular and the plural. In addition, when a range is described in an embodiment, it is considered that the invention includes an individual value that falls within the range (unless otherwise stated), and it is the same as describing each individual value that constitutes the range in the detailed description. Finally, unless there is an explicit description of the order or contrary description for the steps constituting the method according to the embodiment, the steps may be performed in any suitable order. The embodiments are not necessarily limited to the order in which the steps are described. Any use of examples or exemplary terms in the embodiments is merely intended to elaborate the embodiments and is not necessarily intended to limit the scope of the embodiments. Furthermore, those skilled in the art will appreciate that various modifications, combinations and variations may be made according to design conditions and factors within the scope of the present disclosure or their equivalents.

What is claimed is:

1. A display device, comprising:
a display module including a first non-folding area, a second non-folding area, and a folding area disposed between the first non-folding area and the second non-folding area, the first non-folding area, the second non-folding area, and the folding area are each disposed in a first direction;
a panel support disposed under the display module; and
a plate disposed under the panel support,
wherein a first auxetic structure having a negative Poisson’s ratio is disposed between the panel support and the plate in the folding area, and
wherein the first auxetic structure comprises an auxetic foam.

2. The display device of claim 1, wherein the first auxetic structure includes a first stretchable pattern.

3. The display device of claim 1, wherein an aperture ratio of the first auxetic structure, when the first auxetic structure is unfolded, is 10% or less.

4. The display device of claim 1, further comprising a second auxetic structure disposed between the panel support and the display module in the folding area.

5. The display device of claim 4, wherein the second auxetic structure comprises the auxetic foam.

6. The display device of claim 4, wherein the second auxetic structure includes a second stretchable pattern.

7. The display device of claim 4, further comprising a buffer having a positive Poisson’s ratio at an edge of the second auxetic structure along the first direction.

8. The display device of claim 1,
wherein the plate includes a first plate and a second plate disposed in the first direction,
wherein the display device further includes a third auxetic structure disposed between the first plate and the second plate, and
wherein the third auxetic structure comprises the auxetic foam.

9. The display device of claim 8, wherein the third auxetic structure is attached to a first plate or a second plate.

10. The display device of claim 1, wherein the auxetic foam comprises at least one of urethane, expanded polytetrafluoroethylene (ePTFE), polyvinyl chloride (PVC), polymethacrylimide (PMI), or low-density polyethylene (LDPE).

11. A display device, comprising:
a display module including a first non-folding area, a second non-folding area, and a folding area disposed between the first non-folding area and the second non-folding area, each of the first non-folding area, the second non-folding area, and the folding area are disposed in a first direction;
a panel support disposed under the display module; and
a plate disposed under the panel support and including a first plate overlapping the first non-folding area and a second plate overlapping the second non-folding area,
wherein a first auxetic structure having a negative Poisson ratio is disposed between the panel support and the plate in the folding area, and
wherein the first auxetic structure includes a first stretchable pattern.

12. The display device of claim 11, wherein an aperture ratio of the first auxetic structure, when the first auxetic structure is unfolded, is 10% or less.

13. The display device of claim 11, further comprising a second auxetic structure disposed between the panel support and the display module in the folding area.

14. The display device of claim 13, wherein each of the second auxetic structure and the first auxetic structure includes an auxetic foam.

15. The display device of claim 13, wherein the second auxetic structure includes a second stretchable pattern.

16. The display device of claim 13, further comprising a buffer having a positive Poisson’s ratio at an edge of the second auxetic structure along the first direction.

17. The display device of claim 11, further comprising a third auxetic structure disposed between the first plate and the second plate,
wherein the third auxetic structure comprises an auxetic foam.

18. The display device of claim 17, wherein the third auxetic structure is attached to either the first plate or the second plate.

19. The display device of claim 11, wherein the first auxetic structure comprises at least one of urethane, expanded polytetrafluoroethylene (ePTFE), polyvinyl chloride (PVC), polymethacrylimide (PMI) or low-density polyethylene (LDPE).

20. An electronic device, comprising:
a display device, a processor, a memory, and a power module,
wherein the display device includes:
a display module including a first non-folding area, a second non-folding area, and a folding area disposed between the first non-folding area and the second non-folding area, wherein the first non-folding area, the second non-folding area, and the folding area are disposed in a first direction;
a panel support disposed under the display module; and
a plate disposed under the panel support,
wherein a first auxetic structure having a negative Poisson’s ratio is disposed between the panel support and the plate in the folding area, and
wherein the first auxetic structure comprises an auxetic foam.
